(19) United States
(12) Patent Application Publication
(10) Pub. No.: US 2010/0200046 A1
(43) Pub. Date: Aug. 12, 2010

(54) SOLAR PANEL USING A REFLECTIVE STRUCTURE

(75) Inventors: Erik Sauar, Olso (NO); Eckehard Hofmüller, Oslo (NO)

Correspondence Address: BIRCH STEWART KOLASCH & BIRCH, PO BOX 747, FALLS CHURCH, VA, 22040-0747, US

(73) Assignee: Renewable Energy Corporation ASA, Hovik (NO)

(21) Appl. No.: 12/601,789

(22) PCT Filed: May 23, 2008
(86) PCT No.: PCT/NO2008/000181

§ 371 Date: Jan. 25, 2010

Related U.S. Application Data
(60) Provisional application No. 60/940,081, filed on May 25, 2007.

(30) Foreign Application Priority Data
May 25, 2007 (GB) 0710103.3

(51) Int. Cl. H01L 31/052; H01L 31/042; H01L 31/0232

(52) U.S. Cl. 136/246; 136/244; 438/72; 257/E31.127

(57) ABSTRACT

The present invention relates to photovoltaic modules with a plurality of separated photovoltaic elements (3). There is provided a product which utilizes the incident light in the areas in between the elements and a method for production thereof. The area in between the elements is covered by a liquid polymer (2) which is formed into V-grooves and cured and may be covered by a reflective layer.

The present invention relates to improved modules of photovoltaic elements and a method for the production thereof.

### BACKGROUND

Photovoltaic elements within a module are normally placed in rows and columns between a front sheet and a back sheet. Normally only a small fraction of the incident light in the areas in between the elements is reflected such a way on the back sheet that it will be utilized in photoelectric conversion. The addition of reflectors in this area will significantly increase this fraction and therewith the power output of the adjacent photovoltaic elements.

Increasing the spacing between the solar cells and filling this area with the reflective structure may lead to significant savings of silicon solar cells per module by maintaining nearly the same power output.

### PRIOR ART

Present compositions of modules of photovoltaic elements comprise laminated structures which comprise a front sheet and back sheet, where the front sheet serves as protective sheet and is transparent for solar radiation and the back sheet serves as support and/or protection. In between there are disposed distinct photovoltaic elements in rows and columns.

In order to utilize the area between the solar cells, there are made efforts to place reflective elements in between photovoltaic elements. The elements have angels which will guide light from the reflective element to the photovoltaic elements. Several solutions are provided by prior art. U.S. Pat. No. 6,323,415 from Hitachi relates to placement of refractive elements in the same planar orientation as the photovoltaic elements. This placement requires advanced processing equipment in order to align the photovoltaic elements and reflective elements. The reflectivity of the reflective elements is provided by a metallic layer. There is a risk that placing these elements between the solar cells in the same planar orientation may lead to short circuits between adjacent cells.

Another solution is provided by US 2006/0272698 from GE and by PCT2006000489 from REC where the front sheet is modified and provided with a structured surface towards the photovoltaic elements. This modification might weaken the mechanical strength of the front sheet. It is also known that structured glass normally has not so well defined angles, and hence is expected to suffer from lower quality reflection capabilities.

EP 1 080 498 from ASE relates to addition of structured and light reflecting flexible laminated sheet material to extend over the area between the photovoltaic elements. The sheet is defined to have a thickness which is less than the photovoltaic elements. Placing an additional flexible structure into the area between the cells needs particular efforts for the level positioning to ensure the precise alignment of the structure angles.

### OBJECTIVE OF THE INVENTION

The objective of the present invention is to provide a solution where the incident light is collected in between the photovoltaic elements and reflected further to the photovoltaic elements.

A further objective is to provide a process which is aimed especially at the areas in between the photovoltaic elements.

Another objective is to provide a cost effective and fast process to create reflective structures with high precision.

Another objective is to provide photovoltaic modules and methods which may overcome the disadvantages mentioned above.

The objectives of the invention may be obtained by the features as set forth in the following description of the invention and in the appended patent claims.

### DESCRIPTION OF THE INVENTION

Manufacturing of photovoltaic modules comprises a light receiving structure having a substantially transparent front sheet and a back sheet. There are placed a plurality of photovoltaic elements, often in rows and columns, in between the front sheet and back sheet. In order to utilize the incident light which is received in the areas in between the photovoltaic elements, there may be added means which can reflect this light in such a manner that the photovoltaic elements receive the light.

The present invention is based on the surprising discovery that there can be applied a liquid polymer on the back surface of the front sheet or on the front surface of the back sheet which can be formed into V-grooves. The V-grooves can have an angle between 110 and 130°. After the solidification of the formed V-grooves, a reflective layer may be coated onto them. Incident light will be directed to the front surface of the front sheet and there internally reflected towards the adjacent photovoltaic elements. Thereby this incident light can be utilized to generate electric power.

Therefore, one aspect of the present invention relates to the method for production of a photovoltaic module wherein the method comprises:
application of liquid polymer in the areas between the photovoltaic elements on the back surface of the front sheet or on the front surface of the back sheet,
forming of V-grooves into the polymer,

In another aspect, the invention relates to the photovoltaic module comprising reflective V-grooves made from a polymer and locally placed in the areas between the photovoltaic elements on the back surface of the front sheet or on the front surface of the back sheet.

The process allows high precision for applying the reflective elements. The application of the reflective elements does not weaken or harm any of the other elements in the module. The present invention saves silicon resources in a photovoltaic module while maintaining nearly the same power output. Thereby the invention is environmentally friendly and cost efficient.

The solution of the present invention has in addition the advantage that the deposition of the material can be made in many different shapes and thereby be very flexible to current or future designs of photovoltaic elements.

### DETAILED DESCRIPTION

The photovoltaic module of the present invention comprises a light receiving structure which has a substantially transparent front sheet and a back sheet. A plurality of photovoltaic elements are placed in between front sheet and back sheet, wherein reflective V-grooves are made from polymer. The polymer may be transparent in order to allow the incident light to pass the polymer and be reflected on a reflective coating. Types of polymers which are known to be suitable are acrylate, epoxy and polycarbonate. The type of polymer may have very good adhesion to the glass surface and be easily demouldable from the forming equipment.

The V-grooves are locally placed on the back surface of the front sheet in the areas between the photovoltaic elements. The V-grooves of the present invention should be understood as formed traces in the polymer. The form of the V-grooves may be in the form of V, U or be assymetrical whereby having different vertex angels. The skilled person can easily optimize the form of the polymer. The V-grooves may have a vertex angle in the range of 110°-130°. The areas between the photovoltaic elements should be understood to be the area which separates the photovoltaic elements, the area should not be understood strictly and allows overlapping of the V-grooves over the photovoltaic elements e.g. in order to allow for a good aesthetic appearance. The area between the photovoltaic elements may as well comprise about 20% or about 50% or about 80% of the total area of the back surface of the front sheet.

The reflectivity of the V-grooves can be obtained by refraction between 2 materials as for example between the polymer and air. The photovoltaic module of the present invention may be coated by a reflective coating such as an Al, Ag etc. coating partly or totally on the V-grooves.

The front sheet may be a glass plate and it may be highly even in order to ensure minimum distortion in the optical path of the redirected light as for example float glass. The thickness of the front sheet and the height and width of the coating may be optimized in order to avoid interference with the cell interconnectors.

The back sheet may be the support for the reflective polymer coating and may be made of glass or any polymeric material. The reflective structure may be either placed specifically on areas between the cells or more widely. When covering the complete area of the back sheet, the exact positioning of the cells is not important.

The process to produce a photovoltaic module of the present invention comprises application of liquid polymer on the back surface of the front sheet or the front surface of the back sheet in the areas between the photovoltaic elements and forming of V-grooves into the polymer. Forming is done for example by using a master roll, a hot master roll, a master belt or other suitable means with the negative form of the V-grooves, the form might be the exact negative form or be slightly different. Some processing conditions might for example influence the formation of the V-grooves, such that the negative form needs to be optimized such that the intended positive form is achieved after solidification of the coating. In order to achieve a very accurate replication of the V-grooves from the forming equipment, there might be coated a layer on the structure side of the forming equipment to lower the adhesion of the polymer to the forming equipment, e.g by a chromium layer.

The type of the polymer determines, if a curing step accompanies and/or follows forming, as for example curing is usual for acrylate. The purpose of the curing is to fixate the formed V-grooves permanently into the coating. Optimal processing conditions can be easily found by the person skilled in the art. Curing may be done by UV irradiation, electron beam, heat or other. Curing may be done through the front sheet or through the master roll/belt simultaneously or subsequent of the forming.

After formation of V-grooves, there might be applied a reflective coating onto the grooves for example by evaporating or sputtering of a layer of Ag, Al or the like on the structured surface of the V-grooves. Masking may cover the areas which correspond to the photovoltaic elements.

The process of the present invention may further comprise more steps as for example a step of applying a protective coating onto the grooves after deposition of the reflective coating on the V-grooves.

### LIST OF FIGURES

FIG. 1 shows a cross section of a photovoltaic module with reflective structure according to one embodiment of the present invention.

FIG. 2 illustrates the replication process to form the groove structure onto the front cover sheet according to one embodiment of the present invention.

FIG. 3 shows a cross section of a photovoltaic module with reflective structure according to one embodiment of the present invention.

### VERIFICATION OF THE INVENTION

The invention will now be described in greater detail by way of examples of possible embodiments of the invention. These embodiments should not be considered as a limitation of the general inventive idea of applying a polymer on the front sheet and forming V-grooves into the polymer. This general inventive concept is valid for all presently known and foreseeable photovoltaic modules.

### Example 1

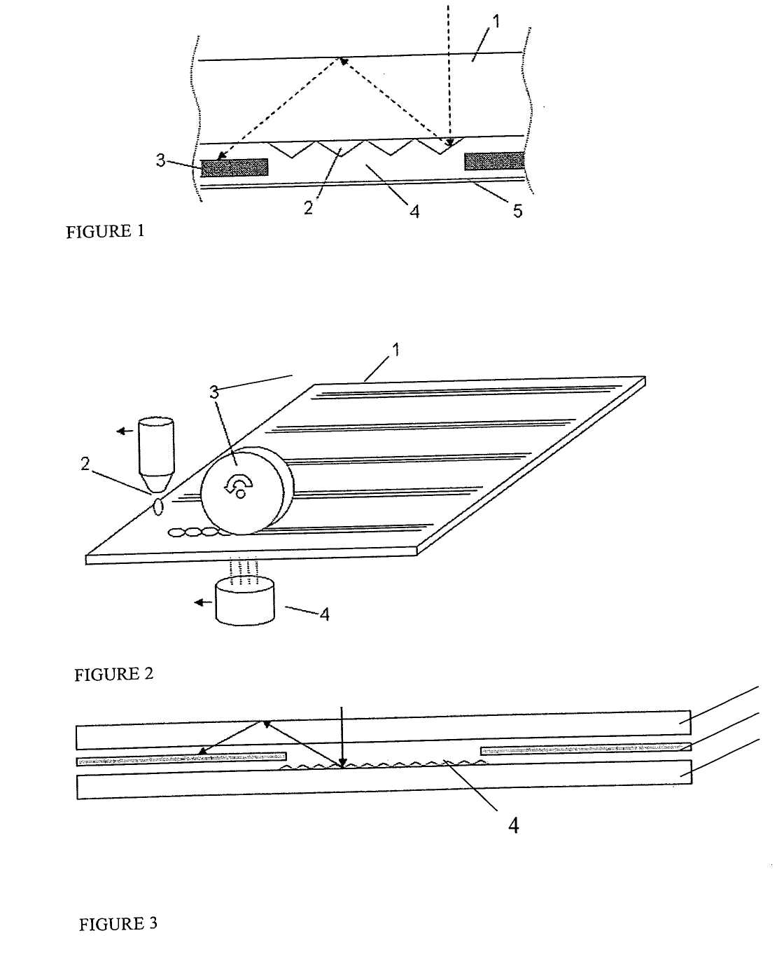

FIG. 1 shows a cross section of a photovoltaic module with reflective structure according to one embodiment of the present invention. The front cover sheet 1 is placed above the back surface sheet 5. The reflective coated structure 2 is applied on the back surface of the front cover sheet 1. The solar cell 3 is placed in a encapsulant material 4. The encapsulant material is optional in the product of the present invention.

The arrows show exemplarily an incident light beam being reflected in the reflective structure and totally internally reflected on the front surface of the front cover 1 through the encapsulant material 4 to the solar cell 3.

### Example 2

FIG. 2 illustrates the replication process to form the groove structure onto the front cover sheet according to one embodiment of the present invention. The front cover sheet 1 is coated by a transparent paint coating 2 in the desired areas which is applied in a dropwise manner. A master structure roll 3 follows the trace of the applied coating and forms V-grooves into the coating. A UV light source 4 cures the applied V-grooves immediately after their formation through the front sheet 1.

### Example 3

In this example there is used a glass plate from low iron glass as float glass with a thickness of 4 mm. As liquid polymer acrylate paint is used which comprises 10% laurylacrylate in order to improve the demoulding properties of the acrylate paint. This material has nearly similar optical properties as glass and provides good adhesion to the glass surface. The liquid polymer is applied at ambient temperature on the back surface of the front sheet. The applied polymer has a width of ca 15 mm and the distance from one stripe to the next stripe is 30 mm.

V-grooves are formed into the applied polymer by using a master belt. The opening angle of the single grooves is 120° on the belt. The breadth of each single groove was ca 60 μm, which resulted in a height of the grooves below 20 μm. With this low structure height the structure will not interfere with the cell interconnectors.

UV light exposed through the glass sheet cures the acrylate. Now the master belt is taken off and a rigid groove structure has been created on the glass sheet.

The structure of the formed groove was accurate and the groove tip roundings had an radius below roughly 0.5 μm.

A 200 nm thick layer of Ag or Al may be added to achieve good reflectivity.

The glass sheet prepared with the reflective stripes may now be processed further to PV modules using 30 mm wide solar cell stripes. Thereby special attention may be paid to the accurate alignment of the solar cell stripes in relation to the reflective stripes.

### Example 4

FIG. 3 shows a cross-section of a photovoltaic module with reflective structure according to one embodiment of the present invention. The front sheet 1 is placed on top of a back sheet of glass 3. Photovoltaic elements 2 are placed in between front sheet 1 and back sheet 3. A polymer layer 4 is coated on the front surface of the back sheet 3. The arrows show exemplarily an incident light beam being reflected in the reflective structure and totally internally reflected on the front surface of the front sheet 1 to the photovoltaic elements 2.

1. A photovoltaic module comprising
a light receiving structure having a substantially transparent front sheet and a back sheet with a plurality of photovoltaic elements placed in between front sheet and back sheet, wherein there is a polymer coating on the back surface of the front sheet or on the front surface of the back sheet at least in the areas between the photovoltaic elements and having the form of reflective V-grooves.

2. The photovoltaic module of claim 1,
wherein the polymer is transparent.

3. The photovoltaic module of claim 2,
wherein the polymer is acrylate, epoxy or polycarbonate.

4. The photovoltaic module of claim 1,
wherein the V-grooves have a vertex angle in the range of 110°-130°.

5. The photovoltaic module of claim 1,
wherein it comprises a reflective coating on the V-grooves.

6. A process to produce a photovoltaic module comprising
a light receiving structure having a substantially transparent front sheet and a back sheet with a plurality of photovoltaic elements placed in between front sheet and back sheet,
wherein it comprises the steps:
application of liquid polymer on the back surface of the front sheet or on the front surface of the back sheet in the areas between the photovoltaic elements or on the full surface,
forming of V-grooves into the polymer.

7. The process of claim 6, wherein it comprises curing wherein curing accompanies and/or follows said forming.

8. The process of claim 6,
wherein it comprises application of a reflective coating onto the grooves after said forming.

9. The process of claim 6,
wherein a transparent polymer is used as said liquid polymer.

10. The process of claim 7,
wherein acrylate, epoxy or polycarbonate is used as said liquid polymer.

11. The process of claim 6,
wherein said forming is done using a master roll, a hot master roll or a master belt with the negative form of the V-grooves.

12. The process of claim 7,
wherein said curing is done by UV irradiation, an electron beam or heat.

13. The process of claim 15,
wherein said curing is done through the said front sheet or through the said master roll/belt.

14. The process of claim 9,
wherein said application of a reflective coating is done by evaporating or sputtering of a layer of Ag, Al or the like.

15. The process of claim 8,
wherein it comprises a step of masking before said application of reflective coating wherein the masking covers the areas on the back surface of the front sheet corresponding to the photovoltaic elements.

16. The process of claim 8,
wherein it comprises a step of applying a protective coating after deposition of the reflective coating.

17. A photovoltaic module comprising
a light receiving structure having a substantially transparent front sheet and a back sheet with a plurality of photovoltaic elements placed in between front sheet and back sheet,
wherein a polymer is coated locally on the back surface of the front sheet or on the front surface of the back sheet in the areas between the photovoltaic elements or on the full surface in a form of reflective V-grooves.

18. The photovoltaic module of claim 2,
wherein the V-grooves have a vertex angle in the range of 110°-130°.

19. The photovoltaic module of claim 3,
wherein the V-grooves have a vertex angle in the range of 110°-130°.
